(19) United States
(12) Patent Application Publication
(10) Pub. No.: US 2006/0197601 A1
(43) Pub. Date: Sep. 7, 2006

(54) Switching device for at least two voltages, corresponding electronic circuit and memory

(75) Inventors: Coloma Bernard, Nantes (FR); Husson Olivier, Nazaier (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: Atmel Nantes SA, Nantes Cedex (FR)

(21) Appl. No.: 11/205,787

(22) Filed: Aug. 17, 2005

(30) Foreign Application Priority Data
Aug. 17, 2004 (FR) 04/08938

(51) Int. Cl. H03F 3/04

(52) U.S. Cl. 330/297

(57) ABSTRACT

A device for switching voltages includes at least two branches each allowing the voltage from a power source to be switched to a single output. Each of the said branches includes at least two transistors, of which at least one is a protective transistor with a dual function: protecting the said power source; and management of at least one leakage current, generated between at least two pins of the said protective transistor.

### TYPE OF INVENTION

This invention falls within the domain of electronics, more specifically that of signal switching to a single output, where each input signal is at a different voltage.

Even more specifically, the invention relates to a voltage switching technique making use of MOS (metal oxide semiconductor) transistors.

The invention can especially be used for any electronic circuit requiring multiple power sources, such as those for Flash or EEPROM (electrically erasable programmable read-only memory) memory chips, etc.

### PREVIOUS STATE OF THE ART

The designs for certain types of electronic circuits, such as Flash and EEPROM memories, use several voltages for the supply.

So, one DC voltage of approximately 1.8V provides the low-voltage supply for the transistors, whereas another source provides a higher-voltage supply to the high voltage transistors.

A voltage switching device is therefore needed, allowing voltages of various different levels to be multiplexed to a single output depending on the instructions given to a control circuit.

Previously, several techniques for switching voltages have been proposed, using transistors as the basis.

However, the majority of these pre-existing techniques have the disadvantage of generating leakage currents or short-circuits between the different sources, due in particular to the direct biasing of the diodes inside the transistor well, or to reverse conduction by the transistors. These techniques therefore do not allow reliable switching between different voltages.

Another technique has been proposed, based on NMOS transistors, which makes it possible to avoid the leakage currents between the different pins of the transistors.

However, a major drawback of this previously described technique is that it requires systems to be used for compensating the transistors' threshold voltage V_{T}; this makes it possible that the voltage to be switched does not drop below the threshold voltage V_{T}.

A technique such as this is relatively complex and costly in terms of the resources needed, since it needs a system for compensating the threshold voltage to be included.

### SUMMARY OF THE INVENTION

Aspects or objections of the invention taken alone or in combination are in particular but not limited to mitigate the disadvantages of the techniques previously in use.

More exactly, one aspect of the invention is to provide a multi-voltage switching technique allowing at least two different source voltages to be switched to a single output, simply and efficiently.

An aspect of the invention specifically aims to propose a technique to do this that will not be expensive in terms of resources (i.e. the number of transistors) and that will be simple to implement.

Another objective of the invention is to provide such a technique that generates little or no leakage current due to incorrect biasing of the transistors.

Yet another aspect of the invention is to provide such a technique that generates little of no short-circuit current between the different source voltages.

The invention has yet another objective in that it provides a technique for this that is less complex and that gives better performance than those previously in use.

These objectives, as well as others that will appear later in this document, are achieved using a voltage switching device comprising of at least two branches, each allowing a voltage supplied from a single source to be switched to a single output.

According to an aspect of the invention, each of the branches in such a device comprises at least two transistors, of which at least one is a protective transistor ensuring a double function, namely:

protecting the supply, and

handling at least on leakage current, generated between at lease two pins of the protective transistor

To each of these branches that are able to switch a voltage, this aspect proposes adding at least two transistors in series (at least one of which is a protective transistor), in turn allowing the source for the given branch to be protected against any short-circuit currents arising from the output of the switch (the said single output), and avoiding leakage currents due to the direct biasing of a diode within the well.

In this way, this aspect proposes a simple, efficient and adjustable switching method for one voltage (out of at least two) to a single output, all the while checking the currents generated between the voltage switch's output and the various supply voltages, which is something that the previously available systems did not envisage.

It should be noted that the selected branch refers here, and throughout the rest of the document, to the branch that is connected to the switch's output and which carries the voltage that is to be switched.

An advantage is that the said transistors are PMOS type transistors.

So, an aspect of the invention relies on an entirely novel and inventive approach to switching voltages within a multi-voltage system. Indeed, previously used techniques did not use PMOS transistors in voltage switching systems, due to the problem of reverse conduction that this type of transistor has, generated when the voltage at the PMOS transistor's drain rises to a voltage that is higher than that at the transistor's gate.

The preferred method ensures protection of the power supply by placing the protective transistor(s) at the end of the branch, connected to the said single output.

The drain of the protective transistors is thus linked to the output of the switch, the said single output.

So, when one branch of the switch has been selected, the gate of each of the protective transistors on the other branches is set to the same potential as the selected branch, i.e. the voltage coming from the supply that is connected to the first end of the selected branch, if this voltage is higher than the circuit's supply voltage (DC). In this case, the protective transistors for each of the non-selected branches, positioned at the second end of each of the branches, are therefore blocked.

The gate of each of the protective PMOS transistors is therefore at the same potential as the drain of these transistors, which is in turn connected to the switch's output, and there can thus not be any short-circuit current between the different voltage sources.

The device described therefore operates relatively simply, by blocking the transistors of certain branches, depending on which branch has been selected. More precisely, when one branch is selected, certain PMOS transistors in the other branches are blocked.

It is also beneficial that the leakage currents are controlled by a connection between the well of the protective transistor and the single output of the switch.

This suppresses the leakage currents due to the direct biasing of a diode within the well, at least partially, by connecting the wells of the protective transistors to the switch's output and not to the branch's supply, which is how it was envisaged in the systems previously used.

Preferably, the device containing the means of selecting one of the branches (carrying the voltage to be switched to the single output) has a means on at least one of the branches of reducing a short-circuit generated while making the selection.

This means of reducing consists in particular of at least a delay system, comprising at least two inverters in series.

This allows the selection of one branch and/or the deselection of the other branches to be delayed by a certain amount, just a few nanoseconds. This delay system prevents a current from passing between a newly selected branch and the branch that was previously selected, while the deselection is occurring.

So, the delay system waits for the transistor in the previously selected branch to be completely deselected (i.e. blocked) before enabling the new branch.

An advantageous way of implementing an aspect of the invention would be as follows. At least one branch (the first type of branch) comprises two level shifters, two delay systems, one inverter and at least two high-voltage PMOS-type transistors in series. At least one other branch (the second type of branch) comprises an inverter and at least three high-voltage PMOS-type transistors in series, at least two of which handle the leakage currents.

The voltage switched by the second-type branch comes from a low voltage DC supply.

In this way, each of the branches contains a means of protecting the supply, controlling the leakage currents, and reducing any short-circuit current.

The invention also covers memories containing a voltage switching device such as that described above.

The invention also covers the corresponding electronic switching circuit.

### LIST OF DIAGRAMS

Other features and benefits of the invention will become clear when reading the following description of one preferred way of implementing it, given by way of a simple and non-exhaustive example, plus the attached drawings, including:

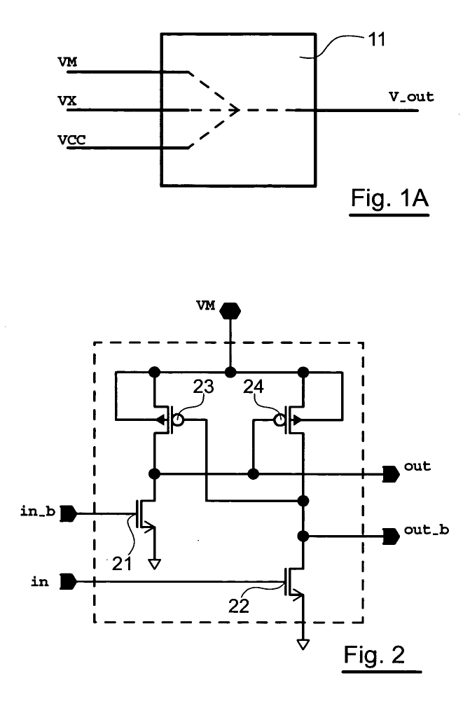

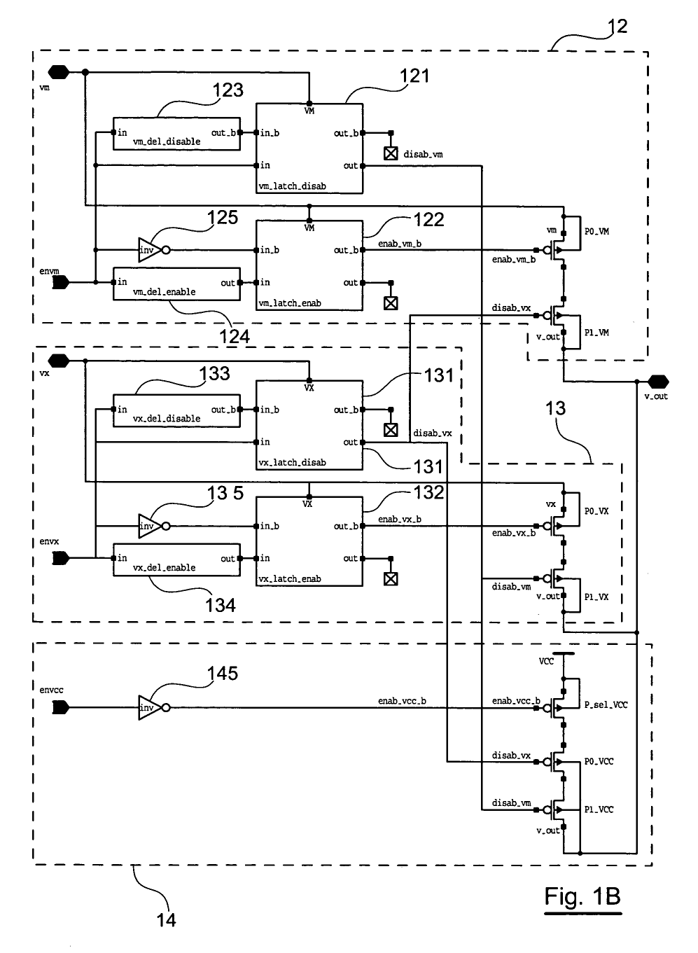

FIG. 1A, illustrating the general principle of a multi-voltage switching device according to the invention, and FIG. 1B, showing a corresponding circuit diagram;

FIG. 2, showing the internal diagram for the level shifters in the electronic circuit of FIG. 1B;

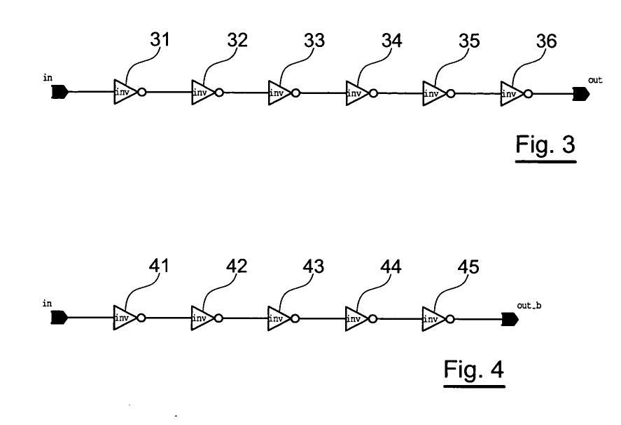

FIGS. 3 and 4, showing the internal diagrams for the delay systems in the electronic circuit of FIG. 1B;

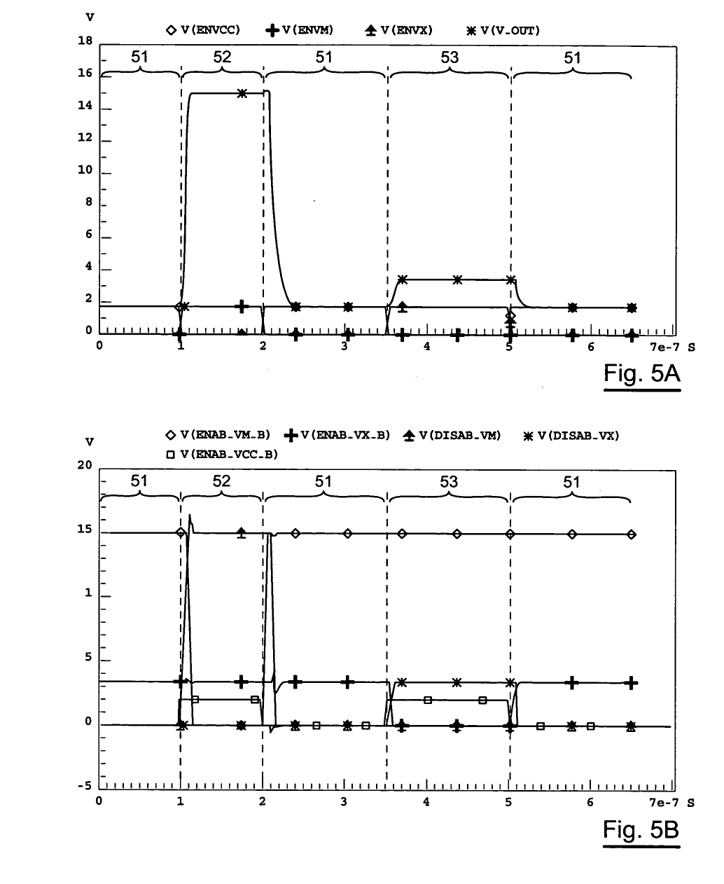

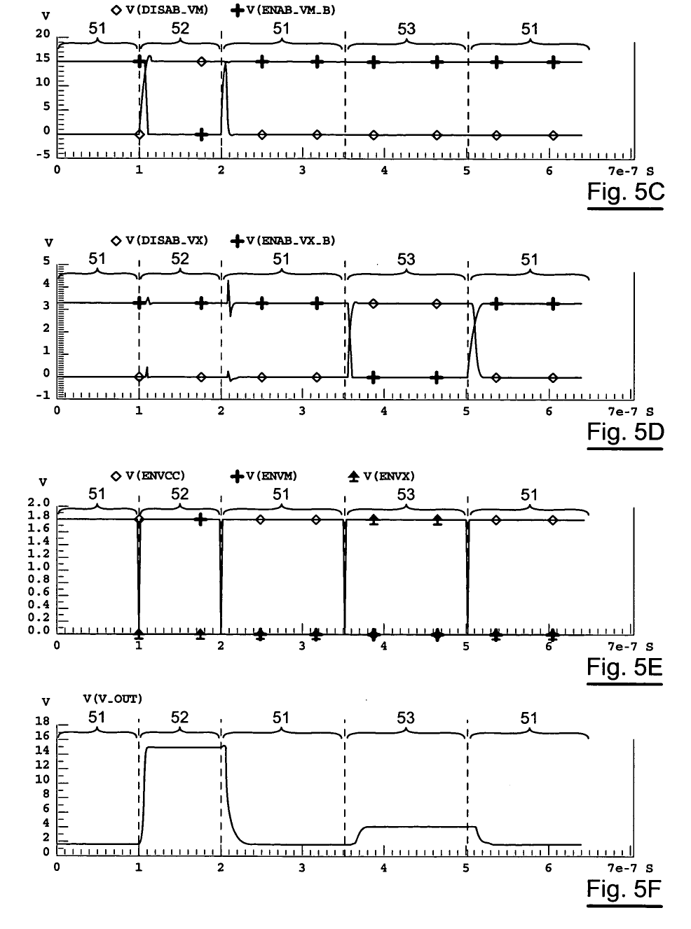

FIGS. 5A to 5F, showing typical curves for the voltage carried by the different signals of the electronic circuit in FIG. 1B, as a function of time.

### DESCRIPTION OF A METHOD OF IMPLEMENTING THE INVENTION

A general principle behind an aspect of the invention relies upon using high voltage PMOS transistors in series in each of the branches that switch a supply voltage to the single output.

According to an aspect of the invention, at least one of these transistors, known as the protective transistor, allows the supply for the branch to which it belongs to be protected against short-circuit currents and allows the leakage currents generated by incorrect biasing of the transistor to be suppressed (or at least reduced) by connecting the well of each of the protective transistors to the switch's output.

A delay system can also be inserted in the various branches, of a type that prevents short-circuit currents during the selection and/or deselection of the various branches.

Using FIG. 1A, the general principle of the device for switching voltages is presented.

A device such as this (11) has at least two input signals carrying a supply voltage, and just one output signal, carrying the supply voltage of the selected branch.

For the sake of simplicity, we will restrict ourselves here (and in the rest of the document) to describing the case of a multi-voltage switching system with three input supply voltages.

Someone skilled in the field will have no difficulty in extending this description to all types of multi-voltage switching systems comprising more than three input supply voltages.

In this case, for example, there are three input supply signals to the voltage switching device (11):

the first signal VM, coming from a high voltage supply (for example in the region of 15 volts);

a second signal VX, coming from an intermediate voltage supply (for example in the region of 3 volts);

a third signal VCC, coming from a low voltage supply and providing power for the device (for example in the region of 1.8V for technology in the 0.18-micron range).

The switching device (11) delivers just one output signal V_out, which is going to be equal to either VM, VX or VCC once again, depending on the control signal applied to the device (11).

FIG. 1B gives a more precise illustration of the way the invention operates in an electronic multi-voltage switching circuit.

As explained earlier using FIG. 1A, a multi-voltage switching circuit such as this has three input supply signals (VM, VX and VCC, where VM carries a supply at about 15V, VX at about 3V and VCC at about 1.8V) and one output signal V_out, which is equal to either VM or VX or VCC.

The multi-voltage switching circuit also has three control signals, envm, envx and envcc that enable the switching of the various branches.

These control signals, activated at the higher potential (i.e. VCC, the voltage VCC that powers the whole of the electronic circuit), allow the branch carrying the corresponding voltage to be selected and switched.

The following table therefore defines the value of the voltage of the output signal V_out as a function of the control signals, with a high level being shown as a ‘1’ and a low level being shown as a ‘0’:

| envm | envx | envcc | V_out |
|---|---|---|---|
| 1 | 0 | 0 | VM |
| 0 | 1 | 0 | VX |
| 0 | 0 | 1 | VCC |

In this way, the electronic circuit defined by an aspect of the invention can be seen as three branches, each of which transfers one voltage to the switch's output V_out:

the first branch (12), switching voltage VM to the single output V_out;

a second branch (13), switching voltage VX to the single output V_out; and

a third branch (14), switching voltage VCC to the single output V_out.

Each branch comprises at least two high voltage PMOS transistors in series, with the drain of each transistor being connected to the source of the next transistor and the drain of the last transistor in the series of transistors being connected to the single output of the switch (signal V_out).

According to an aspect of the invention, the well of the last transistor, known as the protective transistor, is also connected to the output of the switch.

Having a protective transistor such as this placed at the end of each of the branches and connected to the output of the switch allows protection against short-circuit currents coming from the output of the switch at the same time as reducing the leakage currents caused by incorrect biasing of the transistor.

The branches carrying the various voltages do not always consist of the same number of transistors and may contain several protective transistors in series.

So, two types of branches are distinguishable:

the first type of branch switches a voltage that is not the same as the circuit's power supply, i.e. different from VCC;

a second type of branch switches the circuit's own supply voltage, i.e. VCC

So, as illustrated in FIG. 1B, the first branch (12) and the second branch (13) have the same structure and belong to the first type.

More precisely, the first and second branches (12 and 13 respectively) contain:

two high voltage level shifters vm_latch_disab (121) and vm_latch_enab (122)—or vx_latch_disab (131) and vx_latch_enab (132) respectively—for converting the voltage carried by the control signals at the high level (VCC) to their supply voltages (VM and VX respectively);

two delay systems vm_del_disable (123) and vm_del_enable (124)—or vx_del_disable (133) and vx_del_enable (134) respectively—for preventing a current passing between a newly selected branch and the branch previously selected while the latter is being deselected;

an inverter (125 and 135 respectively); and

two high voltage PMOS transistors in series (P0_VM and P1_VM, or P0_VX and P1_VX respectively), of which one protective transistor (P1_VM and P1_VX respectively) provides protection for the power supply and reduces the leakage currents.

The drains of transistors P0_VM and P0_VX are this connected to the source of transistors P1_VM and P1_VX respectively, and the drain of transistors P1_VM and P1_VX (as well as their wells) are connected to the switch's output.

The supply signals VM and VX power each of the two high voltage level shifters vm_latch_disab (121) and vm_latch_enab (122)—or vx_latch_disab (131) and vx_latch_enab (132) respectively. This signal is also connected to the source of the transistors P0_VM and P0_VX respectively, which are themselves connected to the wells of the transistors (P0_VM and P0_VX respectively).

The control signals envm and envx are respectively connected to:

the first input of level shifters vm_latch_disab (121) and vx_latch_disab (131), through the delay systems vm_del_disable (123) and vx_del_disable (133);

a second input of level shifters vm_latch_disab (121) and vx_latch_disab (131);

the first input of level shifters vm_latch_enab (122) and vx_latch_enab (132), through the inverters (125 and 135); and

a second input of level shifters vm_latch_enab (122) and vx_latch_enab (132) through the delay systems vm_del_enable (124) and vx_del_enable (134).

The outputs of high voltage level shifters vm_latch_disab (121) and vx_latch_disab (131), labelled disab_vm_b and disab_vx_b respectively, are connected to the gate of at least one protective transistor of each of the other branches, i.e. the gates of transistors P1_VX and P1_VCC (or P1_VM and P0_VCC respectively).

The outputs of high voltage level shifters vm_latch_enab (122) and vx_latch_enab (132), labelled enab_vm_b and enab_vx_b respectively, are connected to the gate of the first transistor in the series of high voltage PMOS transistors for its branch, i.e. P0_VM or P0_VX respectively.

The third branch (14), allowing the circuit's supply voltage VCC to be switched, is the second type of branch.

More precisely, this third branch (14) contains an inverter (145) and three high voltage PMOS transistors in series, P_sel_VCC, P0_VCC and P1_VCC, of which two (P0_VCC and P1_VCC) are protective transistors that protect the power supply and reduce leakage currents.

The supply signal VCC powers the source of the first transistor in the series of three, namely P_sel_VCC. The drain of transistor P_sel_VCC is connected to the source of transistor P0_VCC, the drain of transistor P0_VCC is connected to the source of transistor P1_VCC and the drain of transistor P1_VCC is connected to the switch's output.

The well of transistor P_sel_VCC is connected to the supply VCC, and the wells of transistors P0_VCC and P1_VCC are connected to the voltage switch's single output.

The control signal envcc is connected to inverter 145. The output of inverter 145, labelled enab_vcc_b, is connected to the gate of transistor P_sel_VCC.

In this way, the internal control signals enab_vm_b, enab_vx_b and enab_vcc_b coming from level shifters vm_latch_enab (122), vx_latch_enab (132) and inverter 145, active when the signal is low, allow the PMOS transistors in the selected branch to conduct.

The internal control signals disab_vm_b and disab_vx_b coming from level shifters vm_latch_disab (121), vx_latch_disab (122), active when the signal is high, allow the PMOS transistors in the non-selected branches to be blocked.

Using the techniques previously available, if the well of a PMOS transistor is supplied with a voltage that is less than the tension at the source of the transistor, a leakage current could appear due to the direct biasing of a diode within the well.

On the other hand, the type N wells of the protective PMOS transistors (P1_VM, P1_VX, P0_VCC and P1_VCC) are connected to the output of the switch, V_out. The voltage on the wells therefore follows the voltage of the output V_out, i.e. that of the selected branch, thereby avoiding leakage currents.

FIG. 2 provides a more precise illustration of the operation of the high voltage level shifters vm_latch_disab (121), vm_latch_enab (122), vx_latch_disab (131) and vx_latch_enab (132).

These four level shifters are identical, with a classical structure based on two NMOS transistors (21 and 22) and two PMOS transistors (23 and 24).

These level shifters, also known as “latches”, are used specifically for converting the voltage carried by the control signal (high level is equal to VCC) into the supply voltage for the branch with which they are associated.

FIG. 3 illustrates the delay systems vm_del_enable (124) in the first branch (12) and vx_del_enable (134) in the second branch (13).

These two delay systems have the same structure, based on six inverters (31 to 36) in series, allowing a delay of a few nanoseconds to be produced.

In the table below, an example is given of an implementation of these inverters (31 to 36) based on MOS transistors, as a function of the dimensions of the N and P channels:

| | Width | Length | Width | Length |
|---|---|---|---|---|
| | of N | of N | of P | of P |
| | channel | channel | channel | channel |
| 31 | 0.42 | 2.8 | 0.42 | 0.18 |
| 32 | 0.42 | 0.18 | 0.42 | 2.8 |
| 33 | 0.42 | 2.8 | 0.42 | 0.18 |
| 34 | 0.42 | 0.18 | 0.42 | 2.8 |
| 35 | 0.42 | 2.8 | 0.42 | 0.18 |
| 36 | 3 | 0.18 | 3 | 0.18 |

FIG. 4 illustrates the delay systems vm_del_disable (123) of the first branch (12) and vx_del_disable (133) of the second branch (13).

These two delay systems have the same structure, based on five inverters 41 to 45 in series, allowing a delay of a few nanoseconds to be produced while also inverting the signal coming into the delay system.

In the table below, an example is given of an implementation of these inverters (41 to 45) based on MOS transistors, as a function of the dimensions of the N and P channels:

| | Width | Length | Width | Length |
|---|---|---|---|---|
| | of N | of N | of P | of P |
| | channel | channel | channel | channel |
| 41 | 0.42 | 0.18 | 0.42 | 3.8 |
| 42 | 0.42 | 3.8 | 0.42 | 0.18 |
| 43 | 0.42 | 0.18 | 0.42 | 3.8 |
| 44 | 0.42 | 3.8 | 0.42 | 0.18 |
| 45 | 3 | 0.18 | 3 | 0.18 |

The delay systems vm_del_enable (124) and vx_del_enable (134) allow the selection of a branch to be delayed, while the delay systems vm_del_disable (123) and vx_del_disable (133) allow the deselection of the other branches to be delayed.

In this way, the delay systems prevent a current from being passed between a branch that has just been selected and the preceding branch, which is in the process of being deselected.

The delay therefore allows the protective transistor in the branch that has just been deselected to reach the completely blocked state before enabling the new branch.

Next, using FIGS. 5A through to 5F, typical curves are given showing the voltage carried by the various signals in the electronic circuit, as a function of time.

FIGS. 5A, 5E and 5F illustrate the levels of each of the control signals envm, envx and envcc (where the high level corresponds to the same potential as VCC, the voltage that powers the whole electronic circuit, and the low level is a potential of 0V), and the corresponding voltage V_out at the switch's output, as a function of time.

FIGS. 5B, 55 and 5D illustrate the voltages of the corresponding internal control signals enab_vm_b, enab_vx_b, disab_vm, disab_vx and enab_vcc_b as a function of time.

Initial State:

More precisely, in the initial state, the control signals envm, envx and envcc will be considered to be at 0 (low).

When control signal envm is in the 0 state, the output enab_vm_b of the high voltage level shifter vm_latch_enab (122) is at voltage VM, thereby blocking the transistor P0_VM, and the output disab_vm of the high voltage level shifter vm_latch_disab (121) is at a potential of 0V, thereby allowing the transistors P1_VX and P1_VCC to conduct.

When control signal envx is in the 0 state, the output enab_vx_b of the high voltage level shifter vx_latch_enab (132) is at voltage VX, thereby blocking the transistor P0_VX, and the output disab_vx of the high voltage level shifter vx_latch_disab (131) is at a potential of 0V, thereby allowing the transistors P1_VM and P1_VCC to conduct.

When control signal envcc is in the 0 state, the output enab_vcc_b given by the inverter 145 is at voltage VCC, thereby blocking the transistor P_sel_VCC.

First Branch (12) Selected—Ref. 52 on FIGS. 5A Through to 5F:

The control signals envm, envx and envcc allow the first branch (12) to be selected, for example, so that the output voltage V_out produced by the switch will be equal to VM.

In this event, the control signal envm is high (equal to VCC), while the other control signals envx and envcc are low (equal to 0V).

As shown in FIGS. 5C and 5E, when the control signal envm is in the 1 state (once again, equal to the high level VCC), the output enab_vm_b is at a potential of 0V, allowing transistor P0_VM to conduct, and the output disab_vm is at voltage VM, thereby blocking the transistors P1_VX and P1_VCC.

While control signal envx remains in the 0 state, the output enab_vx_b is at a voltage of VX, thus blocking the transistor P0_VX, and the output disab_vx is at a potential of 0V, allowing transistors P1_VM and P0_VCC to conduct.

Similarly, since the control signal envcc is still in the 0 state, the output enab_vcc_b is at a voltage of VCC, thus blocking the transistor P_sel_VCC.

As a result, since the transistors P0_VM and P1_VM are now conducting, the output V_out of the switch will be at voltage VM, as shown in FIG. 5F.

It should also be noted that the gates of transistors P1_VX and P1_VCC are at a potential of VM, thus blocking these protective transistors and preventing the supply voltages VX of the second branch (13) and VCC of the third branch (14) from being switched to the switch's output, V_out.

Second Branch (13) Selected—Ref. 53 on FIGS. 5A Through to 5F:

The control signals envm, envx and envcc similarly allow the second branch (13) to be selected, so that the output voltage V_out produced by the switch will be equal to VX.

In this event, the control signal envx is high (equal to VCC), while the other control signals envm and envcc are low (equal to 0V).

While control signal envm remains in the 0 state, the output enab_vm_b is at a voltage of VM, thereby blocking the transistor P0_VM, and the output disab_vm is at a potential of 0V, allowing transistors P1_VX and P1_VCC to conduct.

As shown in FIGS. 5D and 5E, when the control signal envx is in the 1 state (high, equal to VCC), the output enab_vx_b is at a potential of 0V, allowing transistor P0_VX to conduct, and the output disab_vx is at voltage VX, thereby blocking the transistors P1_VM and P1_VCC.

Again, since the control signal envcc is still in the 0 state, the output enab_vcc_b is at a voltage of VCC, thus blocking the transistor P_sel_VCC.

As a result, since the transistors P0_VX and P1_VX are now conducting, the output V_out of the switch will be at voltage VX, as shown in FIG. 5F.

It should again be noted that the gates of transistors P1_VM and P1_VCC are at a potential of VX, thus blocking these protective transistors and preventing the supply voltages VM of the first branch (12) and VCC of the third branch (14) from being switched to the switch's output, V_out.

Third Branch (14) Selected—Ref. 51 on FIGS. 5A Through to 5F:

The control signals envm, envx and envcc similarly allow the third branch (14) to be selected, so that the output voltage V_out produced by the switch will be equal to VCC.

In this event, control signal envcc is high (equal to VCC), while the other control signals envm and envx are low (equal to 0V).

Once again, while the control signal envm remains in the 0 state, the output enab_vm_b is at a voltage of VM, thereby blocking the transistor P0_VM, and the output disab_vm is at a potential of 0V, allowing transistors P1_VX and P1_VCC to conduct.

While control signal envx remains in the 0 state, the output enab_vx_b is at a voltage of VX, thereby blocking the transistor P0_VX, and the output disab_vx is at a potential of 0V, allowing transistors P1_VM and P0_VCC to conduct.

While control signal envcc is in the 1 state (high, equal to VCC), as shown in FIG. 5E, the output enab_vcc_b is at a potential of 0V, allowing transistor P_sel_VCC to conduct.

As a result, since the transistors P_sel_VCC, P0_VCC and P1_VCC are now conducting, the output V_out of the switch will be at voltage VCC, as shown in FIG. 5F.

It should again be noted that the gates of transistors P1_VM and P1_VX are at a potential of 0V, thereby allowing these protective transistors to conduct, but the gates of transistors P0_VM and P0_VX are at potentials of VM and VX respectively, thereby blocking these two transistors.

They thus prevent the supply voltages VM of the first branch (12) and VX of the second branch (13) from being switched to the switch's output, V_out.

The electronic circuit defined by an aspect of the invention thus allows a voltage to be switched to a single output, as a function of the control signals which determine the voltage to be switched and hence the branch to be selected. FIG. 5F therefore represents the voltage V_out at the switch's output, depending on the levels of the input control signals envm, envx and envcc, as illustrated in FIG. 5E.

It can be observed in particular that the gates of the high voltage PMOS transistors are always polarised at the right voltage, which prevents reverse conduction by the PMOS transistors. The phenomenon of reverse conduction occurs specifically when the potential at the source of a transistor rises to a potential that is higher than that of the transistor's gate. An aspect of the invention thus provides a way of correcting for this problem of reverse conduction.

Remember that the electronic circuit contains delay systems vm_del_enable (124) and vx_del_enable (134), allowing the selection of the branches to be retarded, plus delay systems vm_del_disable (123) and vx_del_disable (133) allowing the deselection of the other branches to be retarded.

These delay systems mean that currents passing between the branch just selected and the previously selected branch can be avoided during the deselection.

An aspect of the invention thereby allows several voltages to be switched to a single output by using each of these branches with their PMOS transistors connected in series, the well of the transistor at the end of the series being directly connected to the switch's output, along with any delay systems used, hereby ensuring effective control of leakage currents and short-circuit currents with a minimum number of transistors.

The invention is equally applicable to systems allowing more than three voltages to be switched, by adding at least one high voltage transistor in series with the other PMOS transistors in each of the branches.

The voltage switching device defined by the invention can be used wherever several different voltage supplies are required, for example in memory device (such as Flash or EEPROM memories in particular).

1. A voltage switching device comprising at least two branches, each of which allows a supply voltage to be switched to a single output, wherein at least one of the said branches, hereinafter referred to as a first type of branch, has at least two level shifters, an inverter and at least two transistors in series; and that at least one other of the said branches, hereinafter referred to as a second type of branch, includes an inverter and at least three transistors in series, wherein at least one transistor in each of the said branches is a protective transistor, providing a dual function:
protecting the said power source; and
management of at least one leakage current, generated between at least two pins of the said protective transistor.

2. The device as per claim 1, wherein the said transistors are PMOS type transistors.

3. The device as per claim 1, wherein said protection is provided by the placement of the said protective transistor or transistors at the end of the said branch, connected to the said single output.

4. The device as per claim 1 wherein said management is implemented by connecting the well of the said protective transistor to the said single output.

5. The device as per claim 1 and further comprising means of selecting one of the said branches supplying the voltage to be switched to the said single output, and wherein at least one of the said branches includes a means of reducing a short-circuit current generated during the said selection.

6. The device as per claim 5, wherein said means of reducing includes at least one delay system, made up of at least two inverters in series.

7. The device as per claim 1 wherein said branch of the first type comprises two delay systems.

8. The device as per claim 1 wherein at least two of the minimum of three transistors in the said branch of the second type ensure that leakage currents can be handled.

9. The device as per claim 1 wherein said voltage switched via the said branch of the second type comes from a low-voltage DC supply.

10. The device as per claim 5 wherein at least one of the said transistors in each of the other branches will be blocked when any one of the said branches is selected.

11. An electronic voltage-switching circuit comprising at least two branches, each of which allows a voltage from a power source to be switched to a single output, wherein at least one of the said branches, a said first type of branch, includes at least two level shifters, an inverter and at least two transistors in series; and that at least one other of the said branches, a said second type of branch, includes an inverter and at least three transistors in series, wherein at least one transistor in each of the said branches that is a protective transistor, providing a dual function:
protecting the said power source; and
management of at least one leakage current, generated between at least two pins of the said protective transistor.

12. A memory device having a voltage-switching device comprise at least two branches, each of which allows a voltage from a power source to be switched to a single output; at least one of the said branches, a said first type of branch, includes at least two level shifters, an inverter and at least two transistors in series; at least one other of the said branches, a said second type of branch, includes an inverter and at least three transistors in series; at least one transistor in each of the said branches is a protective transistor, providing a dual function:
protecting the said power source; and
management of at least one leakage current, generated between at least two pins of the said protective transistor.
